(19) United States
(12) Patent Application Publication
(10) Pub. No.: US 2025/0309100 A1
(43) Pub. Date: Oct. 2, 2025

(54) LOW RESISTIVITY CONDUCTOR SUBTRACTIVELY PATTERNED INTERCONNECTS USING LAYER TRANSFER OF MICROSTRUCTURE ENGINEERED THIN FILMS

(71) Applicant: Intel Corporation, Santa Clara, CA (US)

(72) Inventors: Christopher Jezewski, Portland, OR (US); Jin Jimmy Wang, Castro Valley, CA (US); Paul Killian Nordeen, Portland, OR (US); Abhishek Anil Sharma, Portland, OR (US); Andrey Vyatskikh, Hillsboro, OR (US); Paul B. Fischer, Portland, OR (US); Rambert Nahm, Beaverton, OR (US); Abhishek Bang, Portland, OR (US); Michael S. Beumer, Portland, OR (US); Ramanan Chebiam, Hillsboro, OR (US); Ananya Dutta, Portland, OR (US); Mauro J. Kobrinsky, Portland, OR (US); Pratik Koirala, Portland, OR (US); Matthew V. Metz, Portland, OR (US); Akshit Peer, Hillsboro, OR (US); Saima Afroz Siddiqui, Beaverton, OR (US); I-Cheng Tung, Hillsboro, OR (US); Sean Wesley King, Portland, OR (US)

(73) Assignee: Intel Corporation, Santa Clara, CA (US)

(21) Appl. No.: 18/759,580

(22) Filed: Jun. 28, 2024

Related U.S. Application Data
(60) Provisional application No. 63/572,169, filed on Mar. 29, 2024.

(51) Int. Cl. H01L 23/522; H01L 21/768; H01L 23/532; H01L 25/065

(52) U.S. Cl. CPC H01L 23/5226; H01L 21/76877; H01L 23/53204; H01L 21/76819; H01L 25/0655

(57) ABSTRACT

An apparatus comprising an integrated circuit die comprising a first interconnect layer; a second interconnect layer; and a plurality of vias coupling the first interconnect layer to the second interconnect layer; wherein the first interconnect layer comprises a conductive material having a grain size of at least 100 nanometers.

### CROSS REFERENCE TO RELATED APPLICATION

This application claims the benefit of and priority from U.S. Provisional Patent Application No. 63/572,169, entitled “LOW RESISTIVITY CONDUCTOR SUBTRACTIVELY PATTERNED INTERCONNECTS USING LAYER TRANSFER OF MICROSTRUCTURE ENGINEERED THIN FILMS,” filed Mar. 29, 2024, the entire disclosure of which is incorporated herein by reference.

### BACKGROUND

Achieving resistivity design rule targets in interconnects with narrow (e.g., sub-20 nm) pitches presents significant challenges. As the pitch scales down, the complexity and cost of current Cu-based metallization processes rise dramatically, primarily due to the exponential increase in in situ ultra high vacuum (UHV) deposition steps.

### BRIEF DESCRIPTION OF THE DRAWINGS

FIGS. 1-2 illustrate phases of manufacture of a low resistivity subtractively patterned interconnect using a layer transfer of a microstructure engineered thin film, in accordance with any of the embodiments disclosed herein.

FIGS. 3-4 illustrate alternative phases of manufacture of a low resistivity subtractively patterned interconnect using a layer transfer of a microstructure engineered thin film, in accordance with any of the embodiments disclosed herein.

FIGS. 5-6 illustrate alternative phases of manufacture of a low resistivity subtractively patterned interconnect comprising a microstructure engineered thin film, in accordance with any of the embodiments disclosed herein.

FIG. 7 illustrates crystal grain boundaries of different via materials, in accordance with any of the embodiments disclosed herein.

FIG. 8 provides a schematic illustration of a cross-sectional view of an example integrated circuit device, in accordance with any of the embodiments disclosed herein.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, FinFET, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

Achieving resistivity design rule targets in interconnects with narrow (e.g., sub-20 nm) pitches presents significant challenges. As the pitch scales down, the complexity and cost of current Cu-based metallization processes rise dramatically, primarily due to the exponential increase in in situ ultra high vacuum (UHV) deposition steps. The increase in cost, combined with the limitations in further scaling the barrier/liner portion of Cu metallization, suggests that Cu interconnects may no longer be the most economically viable or lowest resistivity solution.

Promising candidates for next generation interconnects appear to include Ru, Mo, and W, which may be subtractively patterned with low K dielectrics or air gaps between the metal lines.

Various embodiments of the present disclosure provide interconnect architectures which significantly improve interconnect resistance using novel materials and integration schemes, enabling continued scaling for logic interconnect dimensions (e.g., complementary field-effect transistor (CFET) interconnect architectures).

In various embodiments of the present disclosure, a micro-structure engineered ultra-low resistivity conductor material (“interconnect material”) is deposited using an optimized deposition and substrate combination. This interconnect material is then layer transferred onto another interconnect layer and subtractively patterned into interconnects. In general, various viable next-generation interconnects beyond Cu and Ru are epitaxial materials and anisotropic conductors. Epitaxial films cannot feasibly be grown directly on interconnect layers due to the poly-crystalline and amorphous nature of the dielectric materials of interconnect layers. Accordingly, various embodiments of the present disclosure may utilize layer transfer techniques to transfer a film comprising an interconnect material grown on a lattice matched substrate onto an interconnect layer of a semiconductor device (indeed at least some of the films can only be grown on such substrates). In various integration schemes disclosed herein, the films may have large (e.g., grain size greater than 100 nm) and/or single-crystal domains with their lowest electrical resistivity orientation in-plane.

Various embodiments may provide technical advantages, such as simplifying processes (e.g., resulting in less operations) or reducing costs relative to similarly performing interconnect schemes (e.g., continued scaling of the barrier liner portion of Cu interconnects).

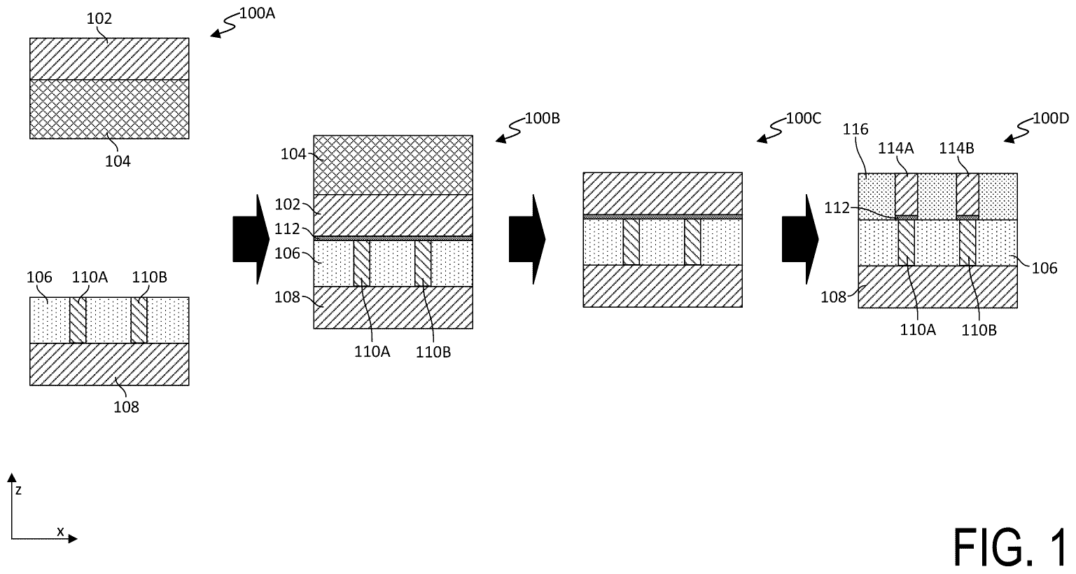

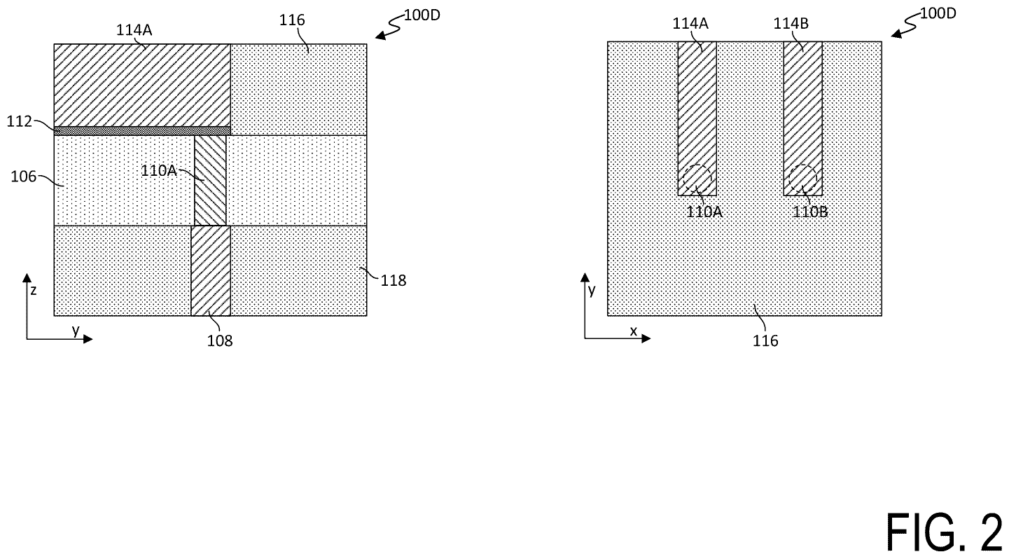

FIGS. 1-2 illustrate phases of manufacture of a low resistivity subtractively patterned interconnect using a layer transfer of a microstructure engineered thin film, in accordance with any of the embodiments disclosed herein.

In phase 100A, a conductor layer 102 comprising the interconnect material is grown on a lattice matched substrate 104 (e.g., of a carrier wafer), e.g., by epitaxial means. “Lattice matched” may refer to close alignment or substantial matching (not necessarily exact alignment or matching) of the crystal lattice structures of the two adjacent materials (e.g., the crystal structures of the materials have similar spacing between and arrangement of atoms). Thus, the conductor layer 102 is lattice matched to the substrate 104.

The conductor layer 102 may be grown on the substrate 104 by depositing a film of the interconnect material. A film of the interconnect material may be deposited using any suitable process, such as physical vapor deposition (PVD), molecular beam epitaxy (MBE), atomic layer deposition (ALD), electroless deposition (ED), electrochemical plating (EP), chemical vapor deposition (CVD), metalorganic chemical vapor deposition (MOCVD), or non-equilibrium deposition techniques such as ion beam deposition (IBD) and pulsed laser deposition (PLD), with careful considerations of the deposition temperatures and lattice-matched substrates used.

In some embodiments, post-processing with annealing may be performed on the interconnect material after deposition as part of the microstructural engineering of the interconnect material (while in other embodiments, the annealing is omitted). For example, an annealing process such as radio frequency (RF) induction heating, radical-assisted annealing, or pulsed laser annealing (PLA) may be performed to recrystallize as-grown films with an emphasis on interlocking a low resistivity orientation of the interconnect material.

In various embodiments, the interconnect material may comprise one or more of pure metals (e.g., Ru, Mo, W, Rh, Ir, Co, Cu), metal alloys (e.g., CuAl₂, CuAl₃, NiAl,), PtCoO₂, PdCoO₂, Topological metals (MoP, CoSi, NbAs), Mxenes and Mbenes (e.g., Cr₂AlC, MnB) low dimensional materials (CeCoIn₅, CoSn) or 2D films, Graphene, intercalated Graphene using FcCl₃, MoCl₃ or other ionic compounds, dopants, organic molecules, or other 2D materials, Bronsted acid, or alkali metal, NbSe₍₁₋ₓ₎Sₓ and TaSe₍₁₋ₓ₎Sₓ, or other intercalated 2D materials.

At least some of these interconnect materials may exhibit lower resistivity and higher conductivity as their crystal grain size increases and as single crystalline thin films (e.g., the entire conductor layer 102 could be a single crystal of an interconnect material on a wafer). The crystal grain size may refer to the average diameter (or longest dimension) of individual crystals (also referred to as grains) within a polycrystalline material (where multiple crystals that have respective crystallographic orientations are packed together). The crystal grain area may refer to the average area of the individual crystals. In various embodiments, the crystal grain size of the conductor layer 102 is greater than about 15 nm. In particular embodiments, the crystal grain size may be greater than about 100 nm (which may provide very low resistivity as well as provide a strong indication that the interconnect material was grown on a lattice matched substrate as opposed to an amorphous layer such as a dielectric). In some embodiments, the crystal grain area may be greater than about 175 nm². In some examples, if the substrate 104 is a wafer having a diameter of 300 mm, the crystal grain size of various conductor layers contemplated herein may range from about 15 nm all the way up to 300 mm (if the conductor layer is a single crystal), and the crystal grain area may range from about 175 nm² up to 70,695 mm² (again if the conductor layer is a single crystal).

Furthermore, at least some of these materials exhibit anisotropic conductivity when microstructure engineering of their ultra-low resistivity conduction direction is oriented in-plane through epitaxial relationship with the substrate and deposition conditions. Anisotropic materials have a directional dependence to their conduction. When such materials are grown in a preferred direction (e.g., in the plane of the wafer), the materials may exhibit lower resistivity and higher conductivity than when they are grown in a different direction. However, growing such materials in the preferred directions on an amorphous material (e.g., a dielectric such as SiO₂) with vias dispersed in the dielectric (as is commonly found in an interconnect layer), is extremely difficult if not impossible. Accordingly, as proposed herein in some of the embodiments, such materials may instead be grown on a lattice matched substrate carrier wafer (e.g., 104) and then transferred to an interconnect layer in order to function as a suitable interconnect material.

Examples of interconnect materials that may exhibit anisotropic conductivity when microstructure engineering of their ultra-low resistivity conduction direction is oriented in-plane through epitaxial relationship with the substrate and deposition conditions include Ru, CoSn, PtCoO₂, PdCoO₂, MoP, NbAs, Cr₂AlC, MnB, CeCoIn5, and 2D films Graphene, intercalated Graphene using FeCl₃, MoCl₃ or other ionic compounds, dopants, organic molecules, or other 2D materials, Bronsted acid, or alkali metal, NbSe₍₁₋ₓ₎Sₓ and TaSe₍₁₋ₓ₎Sₓ, or intercalated 2D versions, NbSe₍₁₋ₓ₎Sₓ, and TaSe₍₁₋ₓ₎Sₓ.

In some embodiments, the interconnect material may have a hexagonal close packed (HCP) structure with the C-axis rotated such that it is in a horizontal plane (e.g., an x-y plane, the same plane of the wafer upon which it is grown). For example, the HCP structure may be rotated 90 degrees relative to a typical vertically oriented HCP structure.

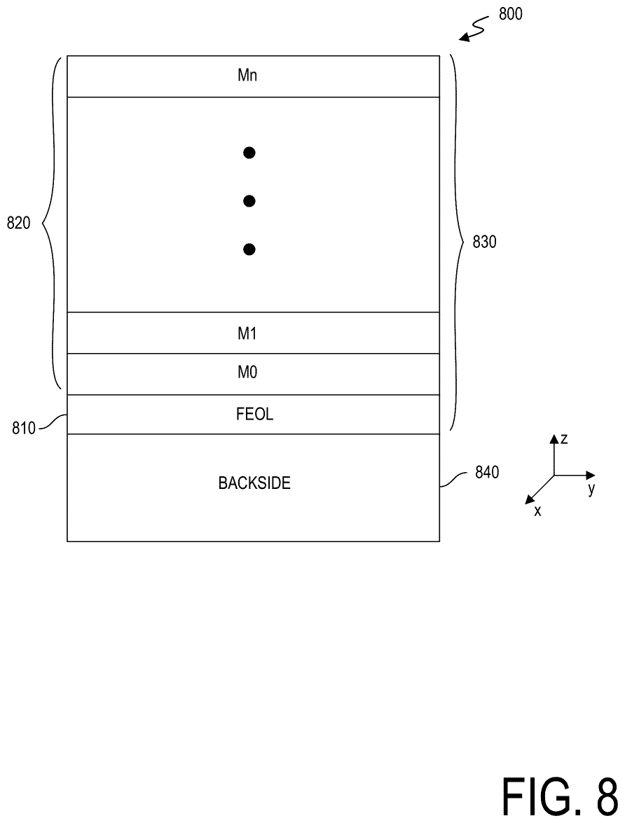

In addition to forming the conductor layer 102 on the substrate 104, a semiconductor wafer is processed in phase 100A. Referring jointly to FIGS. 1 and 2, the processed semiconductor wafer may include a first portion (not explicitly shown) with any suitable components (e.g., including layers formed in a front end of line (FEOL) process and potentially one or more layers formed in a back end of line (BEOL) process, e.g., as described in connection with FIG. 8 or elsewhere herein), a second portion including an interconnect layer comprising a plurality of interconnect lines (e.g., interconnect line 108) and an ILD 118, and a third portion including a layer comprising an interlayer dielectric 106 and a plurality of vias 110 (e.g., 110A and 110B). In a particular embodiment, the vias 110 are created using a single damascene process.

At phase 100B, the conductor layer 102 and substrate 104 (which collectively may be referred to as a carrier wafer) are bonded to the semiconductor wafer (e.g., after flipping the carrier wafer over). In various embodiments, the bonding may be facilitated by an adhesion layer 112.

In various instances, the carrier wafer and/or the semiconductor wafer may be cleaned prior to the bonding (e.g., to remove oxides or residues). For example, one or both of the respective bonding surfaces may undergo a cleaning step without airbreak before deposition of the adhesion layer 112. For example, depending on material types, the clean performed may be thermal, chemical, plasma, or radical based on reducing, oxidizing, or chemical ambient. In various embodiments, a UHV tool may be used to perform the cleaning.

The surface of the carrier wafer and the surface of the semiconductor wafer that are to be bonded together are expected to be relatively smooth (e.g., <0.5 nm Rms) and have a good bonding interface. In some embodiments, two platen polishes are used to slightly recess the ILD 106 to cause the vias 110 to protrude slightly.

The carrier wafer is then bonded to the semiconductor wafer using any suitable method. For example, an adhesion layer material may be formed on the carrier wafer, on the semiconductor wafer, or on both the carrier wafer and the semiconductor wafer. For many of the materials listed above for the interconnect material, adequate bonding may be achieved even if the adhesion layer material is only deposited on the semiconductor wafer surface.

Any suitable adhesion layer material may be applied to one or both of the bonding surfaces. In some embodiments, the adhesion layer material may comprise a conductor, such as a metal. In various examples, the adhesion layer material comprises one or more of Ta, TaN, Ti, TiN, Mo, C (e.g., Graphene, aC, etc.), Zr, or W.

When the bonding surfaces are joined together, the adhesion layer material from one or both of the surfaces forms adhesion layer 112. In various embodiments, adhesion layer 112 may be very thin (so as to limit the resistivity introduced by the adhesion layer between vias and metal lines). In some examples, the adhesion layer 112 has a thickness between 0.3 and 3 nanometers. The adhesion layer 112 may thus be a thin diffusion bonding interface that holds the carrier wafer and the semiconductor wafer together.

The adhesion layer material may be applied to a bonding surface in any suitable manner. In one example, the adhesion layer material is applied during bonding within a vacuum bonder, such as an atomic diffusion bonding (ADB) tool made by Canon/Anelva (e.g., the BC7300), or other suitable equipment. In some instances, under in situ UHV conditions, bonding warpage is reduced using thin sputtered adhesion layers which are deposited on the carrier wafer and the target wafer after the cleaning step and then annealed under low (e.g., ˜150-200° C.) temperatures providing, for example, >1.5 J/m² bonding energy. In another embodiment, a sprinkle of adhesion layer material may be applied to one or both of the bonding surfaces under airbreak, ambient conditions.

In other embodiments, infrared (IR) debond techniques or other suitable techniques could be used to transfer the conductor layer 102 to the semiconductor wafer.

Another unique advantage of the integration scheme disclosed in FIGS. 1-2 is that only one side (e.g., the interconnect layer of the semiconductor wafer that includes the vias) of the bonding interface is patterned at the time of bonding (since the conductive layer 102 will be subtractively patterned in a later step). This reduces complexity by eliminating the requirement for accurate x,y alignment needed in most other bonding applications (e.g., in which interconnects on one side need to be aligned with interconnects on the other side).

At phase 100C, the substrate 104 is separated (e.g., cleaved) from the conductor layer 102 in any suitable manner, leaving the conductor layer 102 over the ILD 106 and vias 110A, 110B. The conductor layer may then be polished to a desired flatness.

In one example, hydrogen and/or deuterium is implanted into the carrier wafer to facilitate the separation of the conductor layer 102 from the substrate 104. The hydrogen and/or deuterium may be implanted either before the deposition of the conductor layer 102 or after the deposition. The implantation of the hydrogen and/or deuterium may result in the presence of hydrogen and/or deuterium proximate to the interface between the substrate 104 and the conductor layer 102. An annealing process may be performed, and the carrier wafer may snap (e.g., silicon of the substrate of the carrier wafer may snap during this step) at a depth at which the hydrogen and/or deuterium was implanted and the substrate 104 may be pulled off, leaving the conductor layer 102 behind. The remaining conductor layer 102 may retain at least some of hydrogen and/or deuterium.

In phase 100D, the conductor layer 102 is subtractively patterned to form interconnect lines 114A, 114B (e.g., M0 lines, M0 lines, M2 lines, etc.). The subtractive patterning process may include removing (e.g., through etching) portions of the conductor layer 102 and replacing these portions with an ILD 116 (and/or airgaps).

In various embodiments, the ILD 116 has the same composition as ILD 106. In other embodiments, the ILD 116 may have a different composition than ILD 106. In some embodiments, ILD 116 may be a low-K ILD.

The interconnect lines 114A, 114B may respectively be connected to vias 110A and 110B. In some instances, discrete portions of the adhesion layer 112 may remain between the vias and the interconnect lines after the subtractive patterning. In various embodiments, the material of the vias 110 has the same composition (e.g., is the same material) as the material of the interconnect lines, while in other embodiments, the materials may be different.

As shown by FIGS. 1 and 2, the interconnect lines 114A, 114B may run in a y-direction, while the interconnect line 108 (which is coupled to interconnect lines 114A, 114B through the vias 110A, 110B) runs orthogonally in an x-direction. The vias (e.g., 110A) may connect the top of the interconnect lines (e.g., 108) of the lower interconnect layer to the bottom of the interconnect lines (e.g., 114A) of the next interconnect layer.

In some embodiments, various phases of the manufacturing process may be repeated (with or without modifications to the individual process steps) to form additional interconnect layers over the interconnect layer comprising interconnect lines 114A and 114B and ILD 116. For example, a layer comprising an ILD and vias may be formed on top of the interconnect layer and then another conductor layer grown on a substrate may be transferred on top of this layer and subtractively patterned to form additional interconnect lines (e.g., which may be orthogonal to the interconnect lines 114A, 114B of the interconnect layer below).

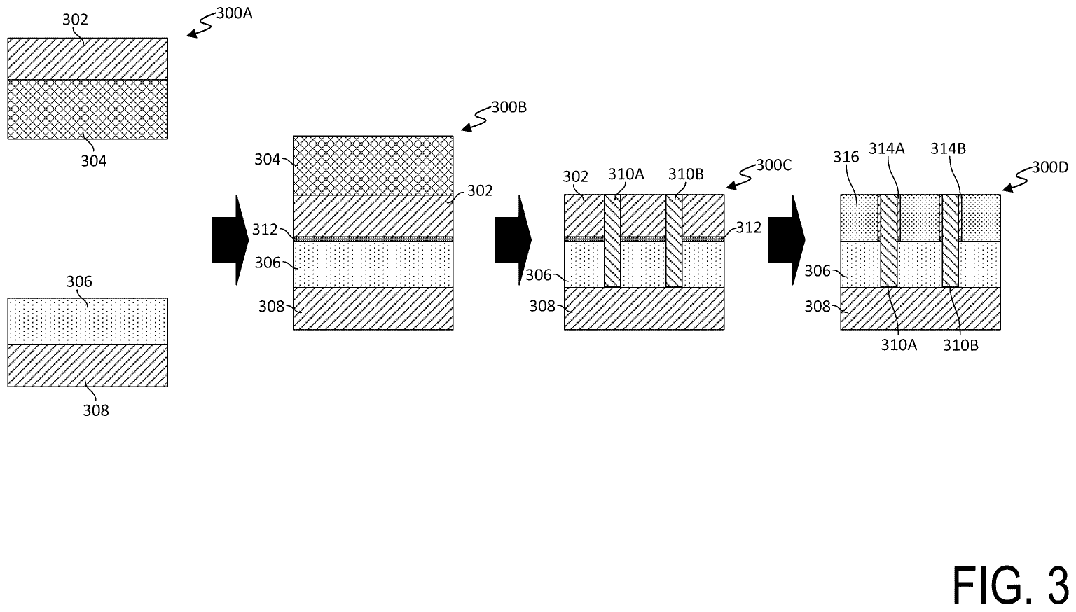

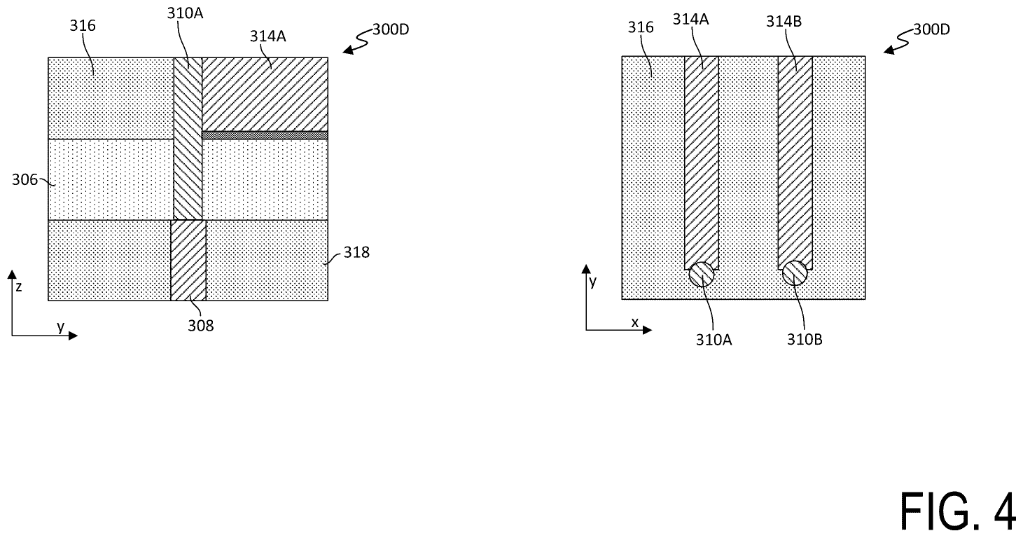

FIGS. 3-4 illustrate alternative phases of manufacture of a low resistivity subtractively patterned interconnect using a layer transfer of a microstructure engineered thin film, in accordance with any of the embodiments disclosed herein. Any of the phases, operations therein, and/or components illustrated or described may have any suitable similar characteristics to those recited in connection with FIGS. 1-2. FIGS. 3-4 illustrate a second integration scheme with the potential for even smoother surfaces for bonding (e.g., ADB bonding) of the conductive layer 302 to the semiconductor wafer. Similar to FIGS. 1-2, FIGS. 3-4 again illustrate conductor growth, layer transfer, and a subtractive patterning process flow.

In phase 300A, conductor layer 302 is formed on substrate 304 in a manner similar to that described above. A semiconductor wafer comprising ILD 306 and an interconnect layer comprising interconnect line 308 is also processed in a manner similar to that described above. In this instance however, the vias are not yet formed in the ILD 306. Accordingly, when the ILD 306 of the semiconductor wafer is cleaned and/or polished, a very smooth surface may be formed that is particularly favorable for bonding to the conductor layer 302. In some embodiments, the bonding surface (e.g., the surface of the ILD 306) of the semiconductor wafer may be atomically smooth, such that variations in height across the surface are on the order of a single atom or less.

At phase 300B, the carrier wafer comprising conductor layer 302 and substrate 304 is bonded to the semiconductor wafer (e.g., as described above). At phase 300C, the substrate 304 is removed. Subsequently, vias 310 (e.g., 310A, 310B) down to the interconnect layer (that comprises interconnect line 308) are formed through the conductor layer 302, the adhesion layer 312, and the ILD 306 (alternatively, the vias could contact any other suitable structure in any suitable alternative layer below the ILD 306 if that layer is not an interconnect layer).

In one embodiment, the vias 310 may be formed by patterning using a lithography mask, etching (e.g., using one or more dry etches) through the conductor layer 302, adhesion layer 312, and ILD 306, and then filling the resulting open cavities (not explicitly shown) with a conductive material.

In various embodiments, the vias 310 may include the same interconnect material as the conductor layer 302. In other embodiments, the vias may include an interconnect material (such as any of those described above or other suitable conductive material) that is different from the interconnect material of the conductor layer 302.

At phase 300D, the conductor layer 316 is subtractively patterned to form interconnect lines 314A, 314B. As is evident in FIG. 4, the interconnect lines 314 may connect to respective vias 310 through sidewalls of the vias (as opposed to a top of the via connecting to a bottom of the respective interconnect line). Thus, a via 310 may extend up through the conductor layer 302 to (or near) the top of the conductor layer 302 and may run alongside and in contact with the interconnect line 314 in the z-direction as illustrated in the lefthand drawing in FIG. 4. As depicted in the righthand drawing in FIG. 4, at least a portion of the outer perimeter (e.g., sidewall) of the via 310 is in contact with the interconnect line 314 as the via runs from the bottom (or proximate thereto) of the interconnect line 314 to the top (or proximate thereto) of the interconnect line.

In various embodiments in which the vias 310 include the same interconnect material as the conductor layer 302, a first portion of a via (e.g., 310A) adjacent to the conductor layer 302 may be epitaxially matched with the interconnect line (e.g., 314A) while the remaining portion (a second portion) of the via is not epitaxially matched with the interconnect line. A crystallographic orientation of the first portion of the via may be aligned or substantially aligned with adjacent material of the interconnect line while a crystallographic orientation of the second portion of the via is not aligned with the crystallographic orientations of the first portion or the interconnect line.

If a different material is used for the vias 310 or the same material is used but in a manner where epitaxial growth from the material of the conductor layer 302 does not occur, the via will not be epitaxially matched with the interconnect line.

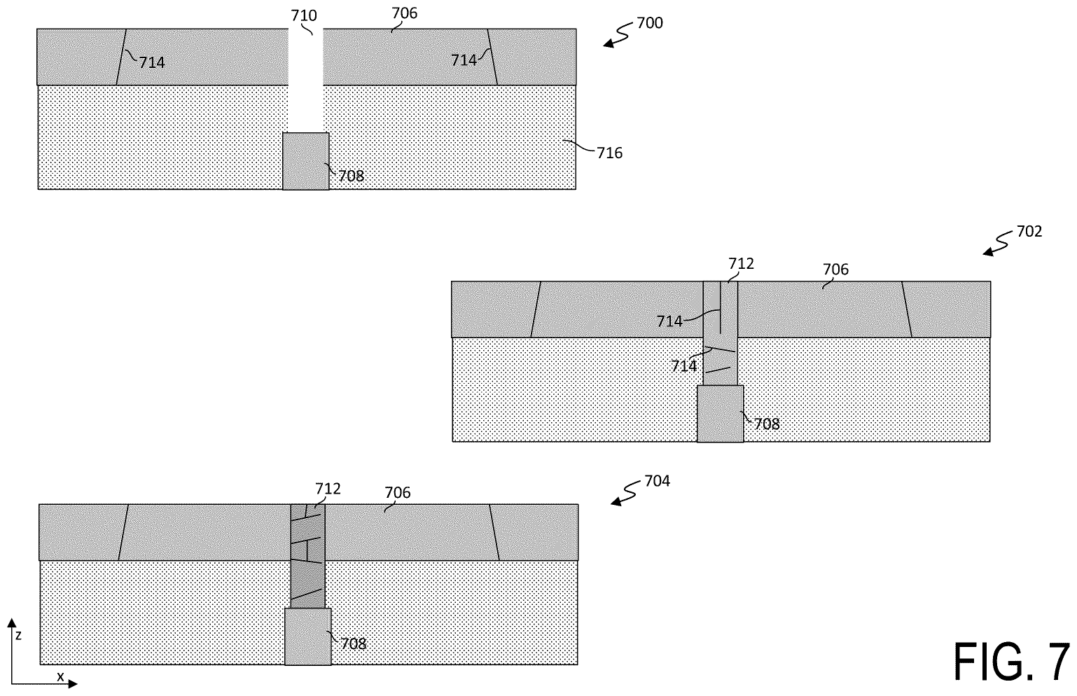

FIG. 7 illustrates an example of this concept. In block 700, a first interconnect layer includes an interconnect line 708. A second interconnect layer includes a layer of interconnect material 706. The first interconnect layer and second interconnect layer (as well as areas in between interconnect lines of the first interconnect layer) are filled by an ILD 716. Before the patterning of interconnect lines in the interconnect material 706, cavities (e.g., 710) for vias are formed. Also depicted are crystal grain boundaries 714 of the conductive material.

In block 702, the cavity is filled with the same material as the interconnect material 706 to form via 712. As depicted, the crystal grain boundary 714 in the upper portion of the via (e.g., the portion that is adjacent to the interconnect material 706) is generally aligned with the crystal grain boundaries of the interconnect material 706. In some instances, the top portion of the via may grow epitaxially from the interconnect material 706. However, the crystal grain boundaries in the lower portion (e.g., the portion that is adjacent to the ILD 716) are not aligned.

Block 706 depicts a scenario in which the cavity is instead filled with a different material from the interconnect material 706 to form via 712. As depicted, the material of the via 712 does not grow epitaxially from the interconnect material 706 as evidenced by the crystal grain boundaries.

In addition to improved bonding surface roughness of the semiconductor wafer due to the absence of vias at phase 300A, the integration scheme depicted in FIGS. 3-4 may have an additional significant benefit when integrating highly anisotropic interconnect materials, since a low resistance edge contact (e.g., the depicted contact between the sidewall of the via and the side of the interconnect line) may be formed between vias 310 and interconnect lines 314 due to the structure of the vias 310. If an edge contact is desired to reduce the resistance for anisotropic and 2D materials, a hybrid of the integration schemes shown in FIGS. 1 and 3 may be used, where incoming first vias (e.g., 110A, 110B) on a semiconductor wafer may be connected to respective second vias formed later in the conductor layer (e.g., 102, 302) and through the adhesion layer, where the second vias have edge contact with respective interconnect lines (e.g., 114, 314) and land on the top of the first vias. In some embodiments, the second set of vias could be made smaller than the first set to facilitate registration.

Such embodiments with sidewall edge contacts may be particularly useful for highly anisotropic interconnect materials that conduct better in the x-y plane (and thus do not perform as well when a via connects to the interconnect line from the bottom). Such embodiments may also be useful for 2D materials that exhibit strong in-plane bonding but do not easily connect to other conductive materials.

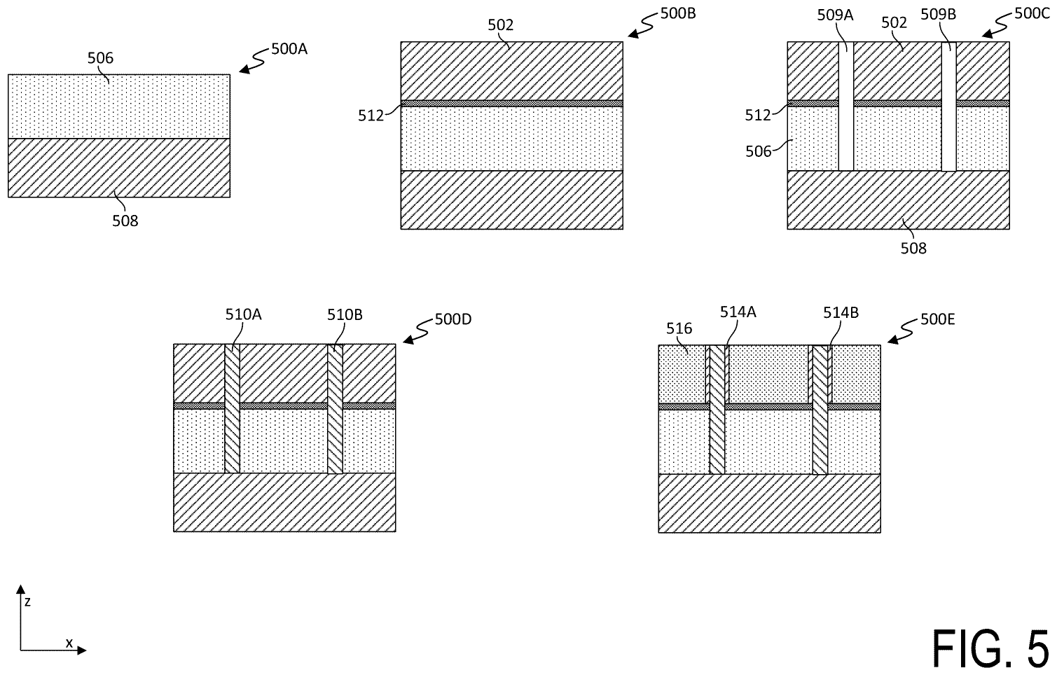

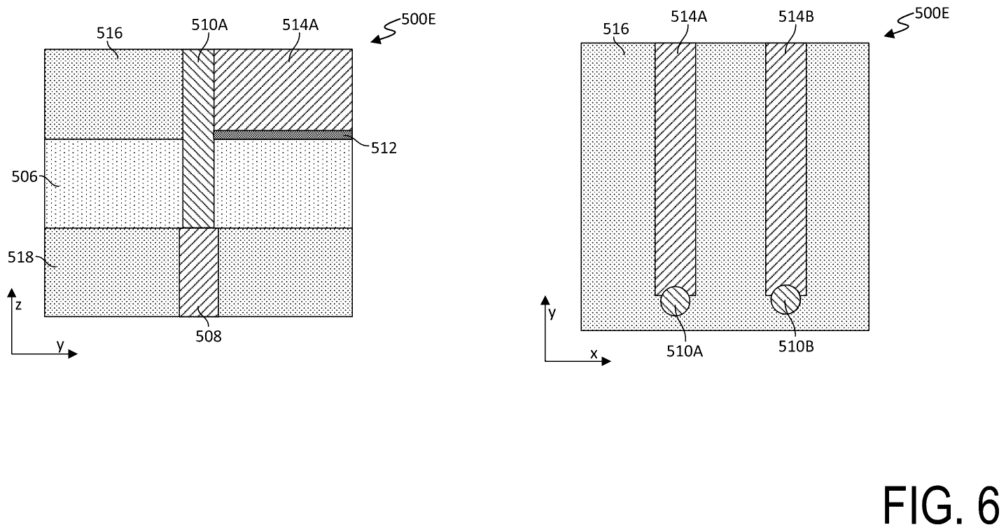

FIGS. 5-6 illustrate alternative phases of manufacture of a low resistivity subtractively patterned interconnect comprising a microstructure engineered thin film, in accordance with any of the embodiments disclosed herein. Again, any of the phases, operations therein, and/or components illustrated or described may have any suitable similar characteristics to those recited in connection with FIGS. 1-4.

At phase 500A, a semiconductor wafer similar to those described above is processed. This wafer includes an ILD 506 above an interconnect layer comprising interconnect line 508. Vias are not yet formed through ILD 506, so the top surface may be relatively smooth.

At phase 500B, an assist layer 512 is formed on the ILD. In various examples, the assist layer 512 may be layer transferred (e.g., from a substrate) or deposited. In various embodiments, the assist layer 512 may be insulative or conductive. In some embodiments, the assist layer 512 is a texturing layer. In other embodiments, the assist layer 512 is a very thin single crystal epitaxial layer (e.g., an epitaxial seed). The assist layer 512 may be sufficiently thin (e.g., less than 5 nm thick in some embodiments) such that the resulting capacitance is not problematic.

The assist layer 512 may texture the interconnect material of the conductor layer 502 into the right direction/orientation. For example, the assist layer 512 may be lattice matched to the highest conductivity crystal plane direction of the interconnect material of the conductor layer (or at least a high conductivity crystal plane direction of the interconnect material), which may or may not be in the same plane as the surface of the semiconductor wafer. In essence, the assist layer 512 may function as a templating layer to create a single crystal or a textured polycrystal in which all multi-crystals are aligned in the desired orientation (e.g., in-plane).

In one example, the assist layer 512 may comprise sapphire with an appropriate lattice matched to the desired conductor layer. As another example, the assist layer 512 may comprise deposited alumina (resulting in a textured layer that facilitates growth of the conductor layer in the desired direction/orientation). In some embodiments, the assist layer 512 comprises SiO₂.

A conductor layer 502 is formed (e.g., deposited) on assist layer 512. The conductor layer 502 may be epitaxial or highly textured and may include, e.g., any of the interconnect materials described above.

At phase 500C, cavities 509A and 509B are formed through the conductor layer 502, assist layer 512, and ILD 506. In a particular embodiment, the cavities may be formed through lithography patterning and dry etching (e.g., by performing an integrated etch), or other suitable method.

At phase 500D, the cavities 509A and 509B are filled with a conductive material (e.g., metal) to form vias 510A, 510B.

At phase 500E, the conductor layer 502 is subtractively patterned to form interconnect lines 514A and 514B that respectively have edge contacts with the vias 510A, 510B.

Depending on whether the assist layer 512 is conductive or insulative, portions of the assist layer 512 may be removed or not removed at various locations in order to achieve the desired conductivity between interconnect lines and/or vias.

In various embodiments, the dimensions of widths of interconnect lines comprising the interconnect materials described herein with grain size greater than 100 nm may be, e.g., within the range of 4 nm-18 nm for logic applications and within the range of, e.g., 20 nm-50 nm for SRAM applications, where both logic and SRAM may have aspect ratios of 1x-8x.

FIG. 8 provides a schematic illustration of a cross-sectional view of an example integrated circuit device (e.g., a chip) 800 that may include structures (e.g., interconnect material) described above. The IC device 800 may include transistors as well as other circuit elements (e.g., resistors, diodes, capacitors, inductors, etc.).

As shown in FIG. 8, the IC device 800 may include a front side 830 comprising a front-end-of-line (FEOL) 810 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 810 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 820.

The front side 830 of the IC device 800 also includes a BEOL 820 including various metal interconnect layers (e.g., metal 0 through metal n, where n is any suitable integer). Various metal layers of the BEOL 820 may be used to interconnect the various inputs and outputs of the FEOL 810.

Generally speaking, each of the metal layers of the BEOL 820, e.g., each of the layers M0-Mn shown in FIG. 8, may include a via portion and a trench/interconnect portion. Typically, the trench portion of a metal layer is above the via portion, but, in other embodiments, a trench portion may be provided below a via portion of any given metal layer of the BEOL 820. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 820, e.g., layers M0-Mn shown in FIG. 8, may include certain patterns of conductive metals, e.g., copper (Cu) or aluminum (Al), or metal alloys, or more generally, patterns of an electrically conductive material (e.g., including carbon based materials) such as the interconnect material described above, formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 800 may also include a backside 840. For example, the backside 840 may formed on the opposite side of a wafer from the front side 830. In various embodiments, the backside 840 may include any suitable elements to assist operation of the IC device 800. For example, the backside 840 may include various metal layers to deliver power to logic of the FEOL 810.

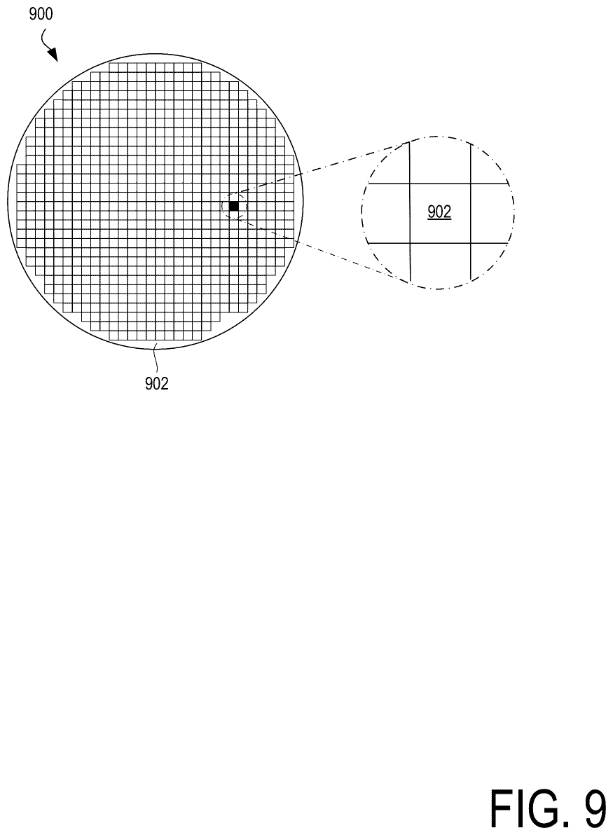

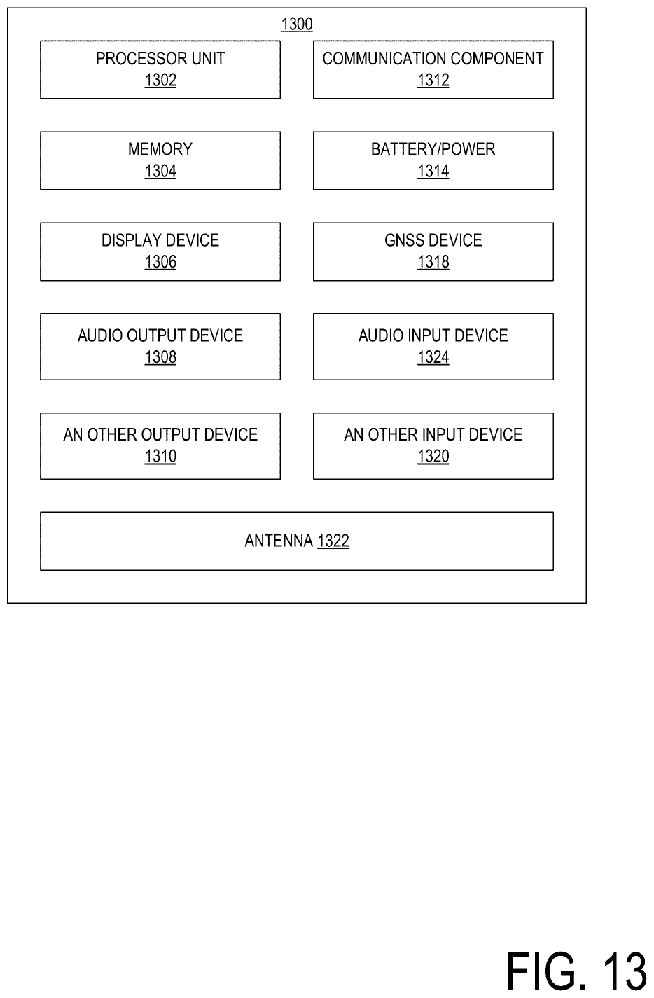

FIG. 9 is a top view of a wafer 900 and dies 902, wherein individual dies may include interconnect material as disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors, supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 900 that include other dies, and the wafer 900 is subsequently singulated.

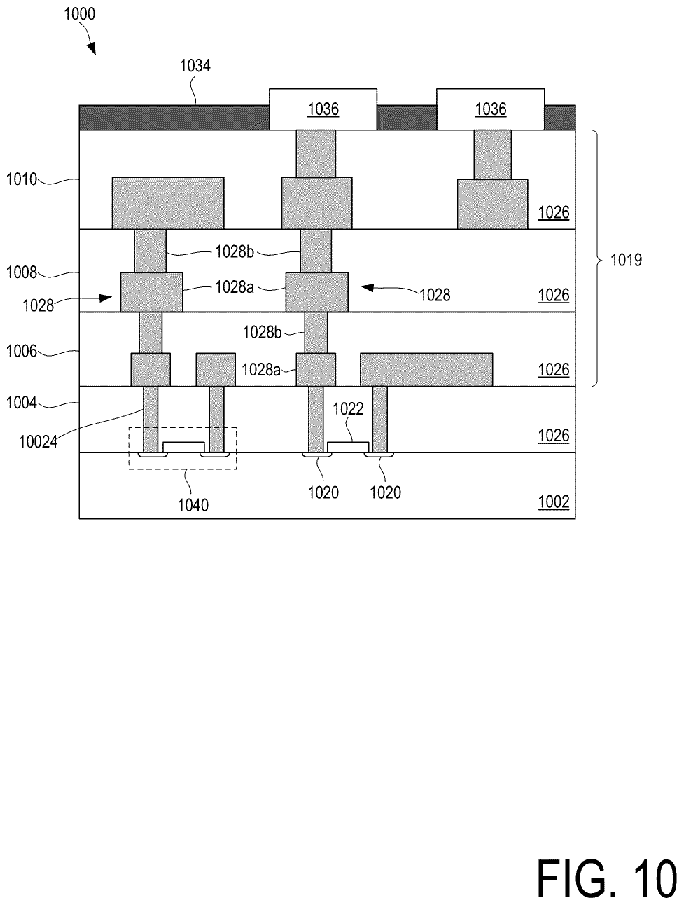

FIG. 10 is a cross-sectional side view of an integrated circuit device 1000 that may include interconnect material as disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

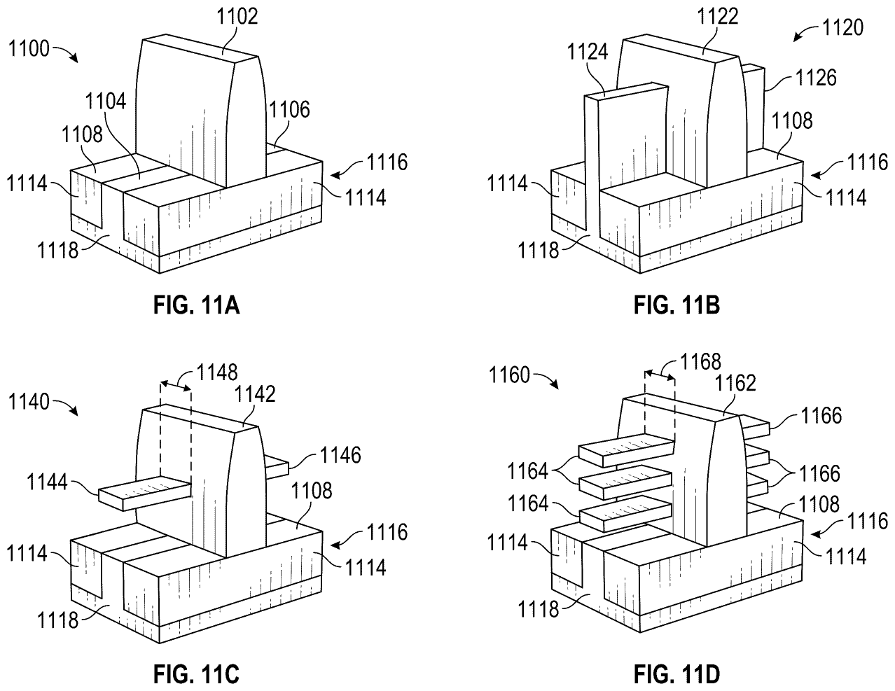

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of or comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 (e.g., lines) may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the integrated circuit device (e.g., die) 1000, and the metallization stack 1019 can be used to route I/O signals from the conductive contacts 1036 to transistors 1040 and any other components integrated into the integrated circuit device (e.g., die) 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

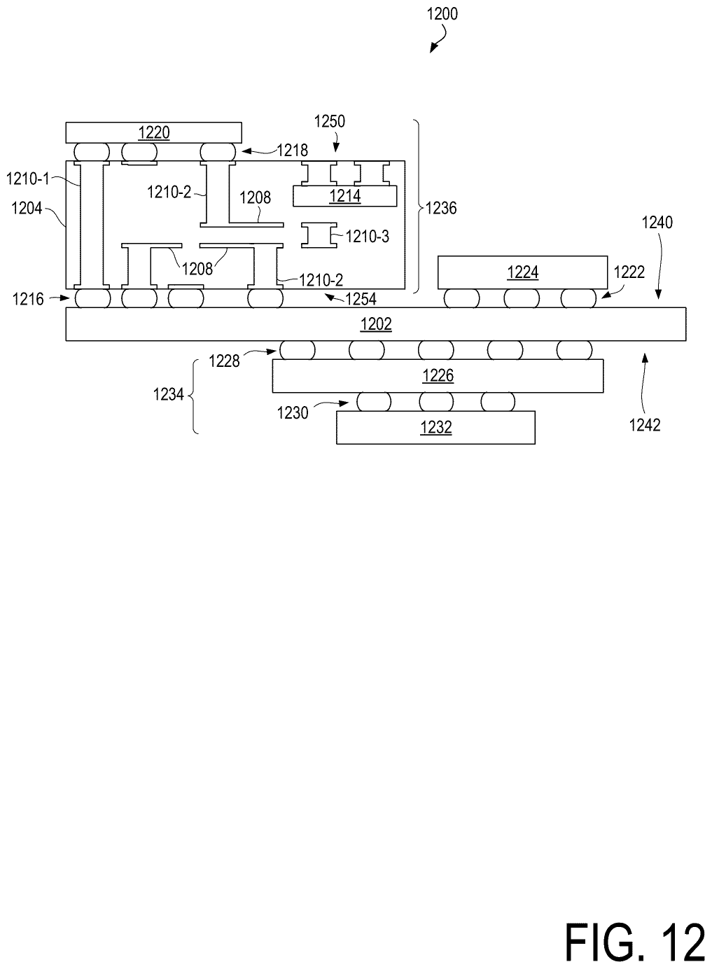

FIG. 12 is a cross-sectional side view of an integrated circuit device assembly 1200 that may include interconnect material as disclosed herein. In some embodiments, the integrated circuit device assembly 1200 may be a microelectronic assembly. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include interconnect material as disclosed herein. For example, any suitable components of the electrical device 1300 may include one or more of the integrated circuit device assemblies 1200, integrated circuit components 1220, integrated circuit devices 1000, integrated circuit dies 902, or other components disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as amplitude modulation (AM) or frequency modulation (FM) radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is next to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising an integrated circuit die comprising a first interconnect layer; a second interconnect layer; and a plurality of vias coupling the first interconnect layer to the second interconnect layer; wherein the first interconnect layer comprises a conductive material having a grain size of at least 100 nanometers.

Example 2 includes the subject matter of Example 1, and wherein the conductive material is formed from a single crystal.

Example 3 includes the subject matter of any of Examples 1 and 2, and wherein the conductive material exhibits anisotropic conductivity.

Example 4 includes the subject matter of any of Examples 1-3, and further including an adhesion layer between the first interconnect layer and the second interconnect layer, the adhesion layer to bond the conductive material of the first interconnect layer to a dielectric material adjacent to the first interconnect layer.

Example 5 includes the subject matter of any of Examples 1-4, and wherein the crystallographic orientation of the conductive material is in-plane with the first interconnect layer.

Example 6 includes the subject matter of any of Examples 1-5, and further including a layer between the first interconnect layer and the second interconnect layer, wherein the conductive material is on the layer and the layer is lattice matched to the conductive material.

Example 7 includes the subject matter of any of Examples 1-6, and wherein a via of the plurality of vias extends from a top of the second interconnect layer through the conductive interconnect material to a top of the first interconnect layer.

Example 8 includes the subject matter of any of Examples 1-7, and wherein the via includes the conductive material.

Example 9 includes the subject matter of any of Examples 1-8, and wherein the via includes a first portion that is epitaxially matched with the conductive material of the first interconnect layer and a second portion that is not epitaxially matched with the conductive material of the first interconnect layer.

Example 10 includes the subject matter of any of Examples 1-9, and wherein the via does not include the conductive material.

Example 11 includes the subject matter of any of Examples 1-10, and wherein the apparatus further comprises a printed circuit board; and an integrated circuit package attached to the printed circuit board, the integrated circuit package comprising the integrated circuit die.

Example 12 includes the subject matter of any of Examples 1-11, and wherein the apparatus further comprises one or more additional integrated circuit packages attached to the printed circuit board.

Example 13 includes an apparatus comprising a first interconnect line in a first interconnect layer, the first interconnect line comprising a conductive material, wherein the conductive material has a grain size of at least 100 nanometers. a second interconnect line in a second interconnect layer; and a via connecting the first interconnect line to the second interconnect line, wherein the via contacts the first interconnect line along a sidewall of the via;

Example 14 includes the subject matter of Example 13, and wherein the apparatus further comprises an adhesion layer under the first interconnect line, wherein the sidewall of the via contacts the adhesion layer.

Example 15 includes the subject matter of any of Examples 13-14, and wherein the via includes a first portion that is epitaxially matched with the conductive material of the first interconnect layer and a second portion that is not epitaxially matched with the conductive material of the first interconnect layer.

Example 16 includes the subject matter of any of Examples 13-15, and wherein the conductive material exhibits anisotropic conductivity.

Example 17 includes the subject matter of any of Examples 13-16, and wherein the conductive material is formed from a single crystal.

Example 18 includes the subject matter of any of Examples 13-17, and further including an adhesion layer between the first interconnect line and the second interconnect line, the adhesion layer to bond the conductive material of the first interconnect line to a dielectric material adjacent to the first interconnect line.

Example 19 includes the subject matter of any of Examples 13-18, and wherein the crystallographic orientation of the conductive material is in-plane with the first interconnect layer.

Example 20 includes the subject matter of any of Examples 13-19, and further including a layer between the first interconnect layer and the second interconnect layer, wherein the conductive material is on the layer and the layer is lattice matched to the conductive material.

Example 21 includes the subject matter of any of Examples 13-20, and wherein a via of the plurality of vias extends from a top of the second interconnect layer through the conductive material to a top of the first interconnect layer.

Example 22 includes the subject matter of any of Examples 13-21, and wherein the via includes the conductive material.

Example 23 includes the subject matter of any of Examples 13-22, and wherein the via includes a first portion that is epitaxially matched with the conductive material of the first interconnect layer and a second portion that is not epitaxially matched with the conductive material of the first interconnect layer.

Example 24 includes the subject matter of any of Examples 13-23, and wherein the via does not include the conductive material.

Example 25 includes the subject matter of any of Examples 13-24, and wherein the apparatus further comprises a printed circuit board; and an integrated circuit package attached to the printed circuit board, the integrated circuit package comprising the first interconnect layer, the second interconnect layer, and the via.

Example 26 includes the subject matter of any of Examples 13-25, and wherein the apparatus further comprises one or more additional integrated circuit packages attached to the printed circuit board.

Example 27 includes a method comprising forming a conductive material on a first wafer comprising a substrate that is lattice-matched to the conductive material; forming a plurality of integrated circuit devices on a second wafer; layer transferring the conductive material from the first wafer to the second wafer; and forming a plurality of interconnect lines from the conductive material.

Example 28 includes the subject matter of Example 27, and wherein a grain size of the conductive material is greater than 100 nanometers.

Example 29 includes the subject matter of any of Examples 27 and 28, and further including forming a plurality of vias between the conductive material and the first interconnect layer, wherein the vias are formed by etching cavities into the conductive material and a dielectric material under the conductive material and filing the cavities with the conductive material.

Example 30 includes the subject matter of any of Examples 27-29, and further including polishing a top surface of the second wafer to cause the surface to be atomically smooth; and bonding the top surface of the second wafer to a surface of the conductive material on the first wafer.

Example 31 includes the subject matter of any of Examples 27-30, and wherein the conductive material is formed from a single crystal.

Example 32 includes the subject matter of any of Examples 27-31, and wherein the conductive material exhibits anisotropic conductivity.

Example 33 includes the subject matter of any of Examples 27-32, and further including forming an adhesion layer between the first wafer and the second wafer, the adhesion layer to bond the conductive material of the first wafer to a dielectric material of the second wafer.

Example 34 includes the subject matter of any of Examples 27-33, and wherein a crystallographic orientation of the conductive material is in-plane with the first wafer.

Example 35 includes the subject matter of any of Examples 27-34, and further including forming a via, wherein the via extends from a top of a second interconnect layer through the conductive material to a top of a first interconnect layer.

Example 36 includes the subject matter of any of Examples 27-35, and wherein the via includes the conductive material.

Example 37 includes the subject matter of any of Examples 27-36, and wherein the via includes a first portion that is epitaxially matched with the conductive material of a first interconnect layer and a second portion that is not epitaxially matched with the conductive material of the first interconnect layer.

Example 38 includes the subject matter of any of Examples 27-37, and wherein the via does not include the conductive material.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
an integrated circuit die comprising:
a first interconnect layer;
a second interconnect layer; and
a plurality of vias coupling the first interconnect layer to the second interconnect layer; wherein the first interconnect layer comprises a conductive material having a grain size of at least 100 nanometers.

2. The apparatus of claim 1, wherein the conductive material is formed from a single crystal.

3. The apparatus of claim 1, wherein the conductive material exhibits anisotropic conductivity.

4. The apparatus of claim 1, further comprising an adhesion layer between the first interconnect layer and the second interconnect layer, the adhesion layer to bond the conductive material of the first interconnect layer to a dielectric material adjacent to the first interconnect layer.

5. The apparatus of claim 1, wherein a crystallographic orientation of the conductive material is in-plane with the first interconnect layer.

6. The apparatus of claim 1, further comprising a layer between the first interconnect layer and the second interconnect layer, wherein the conductive material is on the layer and the layer is lattice matched to the conductive material.

7. The apparatus of claim 1, wherein a via of the plurality of vias extends from a top of the second interconnect layer through the conductive material to a top of the first interconnect layer.

8. The apparatus of claim 7, wherein the via includes the conductive material.

9. The apparatus of claim 8, wherein the via includes a first portion that is epitaxially matched with the conductive material of the first interconnect layer and a second portion that is not epitaxially matched with the conductive material of the first interconnect layer.

10. The apparatus of claim 7, wherein the via does not include the conductive material.

11. The apparatus of claim 1, wherein the apparatus further comprises:
a printed circuit board; and
an integrated circuit package attached to the printed circuit board, the integrated circuit package comprising the integrated circuit die.

12. The apparatus of claim 11, wherein the apparatus further comprises one or more additional integrated circuit packages attached to the printed circuit board.

13. An apparatus comprising:
a first interconnect line in a first interconnect layer, the first interconnect line comprising a conductive material, wherein the conductive material has a grain size of at least 100 nanometers;
a second interconnect line in a second interconnect layer; and
a via connecting the first interconnect line to the second interconnect line, wherein the via contacts the first interconnect line along a sidewall of the via.

14. The apparatus of claim 13, wherein the apparatus further comprises an adhesion layer under the first interconnect line, wherein the sidewall of the via contacts the adhesion layer.

15. The apparatus of claim 13, wherein the via includes a first portion that is epitaxially matched with the conductive material of the first interconnect layer and a second portion that is not epitaxially matched with the conductive material of the first interconnect layer.

16. The apparatus of claim 13, wherein the conductive material exhibits anisotropic conductivity.

17. A method comprising:
forming a conductive material on a first wafer comprising a substrate that is lattice-matched to the conductive material;
forming a plurality of integrated circuit devices on a second wafer;
layer transferring the conductive material from the first wafer to the second wafer; and
forming a plurality of interconnect lines from the conductive material.

18. The method of claim 17, wherein a grain size of the conductive material is greater than 100 nanometers.

19. The method of claim 17, further comprising forming a plurality of vias between the conductive material and a first interconnect layer, wherein the vias are formed by etching cavities into the conductive material and a dielectric material under the conductive material and filing the cavities with the conductive material.

20. The method of claim 17, further comprising:
polishing a top surface of the second wafer to cause the surface to be atomically smooth; and
bonding the top surface of the second wafer to a surface of the conductive material on the first wafer.
